(19) United States
(12) Patent Application Publication
(10) Pub. No.: US 2003/0031081 A1
(43) Pub. Date: Feb. 13, 2003

(54) Semiconductor memory device operating in synchronization with data strobe signal

(75) Inventors: Takanobu Suzuki, Hyogo (JP); Takeshi Hamamoto, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 10/135,512

(22) Filed: May 1, 2002

(30) Foreign Application Priority Data
Aug. 8, 2001 (JP) 2001-240930(P)

(51) Int. Cl. G11C 8/00

(52) U.S. Cl. 365/233

(57) ABSTRACT

A DDR SDRAM includes: an input buffer and a timing adjustment circuit for converting an external data strobe signal into a binary signal and adjusting the timing; a glitch elimination circuit for eliminating a glitch G′ from an output signal of the timing adjustment circuit to produce an internal data strobe signal; and an input buffer and a latch circuit for taking in a data signal in synchronization with the internal data strobe signal. Accordingly, even if an external data strobe signal suffers from a glitch, an internal circuit will not malfunction.

### BACKGROUND OF THE INVENTION

1. Field of the Invention

The present invention relates to a semiconductor memory device, and more particularly to a semiconductor memory device taking in 2N data signals in synchronization with N pairs of a leading edge and a trailing edge included in an external data strobe signal.

2. Description of the Background Art

FIG. 11 is a time chart showing a writing operation of a conventional DDR (Double Data Rate) SDRAM (Synchronous Dynamic Random Access Memory).

In FIG. 11, a write command WRT is input in synchronization with a rising edge (time t0) of an external clock signal CLK, and a data strobe signal DQS and a predetermined number (for example four) of write data signals Dn are input in synchronization with a rising edge one clock cycle after that rising edge. The four write data signals Dn are input in synchronization with each of rising and falling edges of signal DQS. A preamble period T1 at “L (low)” level is provided before the first rising edge of data strobe signal DQS, and a postamble period T2 at “L” level is provided after the last falling edge of signal DQS. After the elapse of postamble period T2, signal DQS is terminated at a reference potential VR.

An internal data strobe signal INTDQS is produced based on signal DQS. Signal INTDQS is a signal produced by converting signal DQS into a binary signal which is in turn delayed by a prescribed amount of time. In synchronization with each of rising and falling edges of signal INTDQS, four write data signals Dn are sequentially taken in, and then the four data signals taken in are sequentially written into selected four memory cells.

In the conventional DDR SDRAM, however, if an overshoot of signal DQS occurs after the elapse of postamble period T2 and a so-called glitch G arises, a glitch G′ also arises in signal INTDQS and results in a malfunction of the internal circuit.

### SUMMARY OF THE INVENTION

Therefore, a main object of the present invention is to provide a semiconductor memory device free from a malfunction even if a glitch occurs in a data strobe signal.

A semiconductor memory device in accordance with the present invention is provided with an input buffer outputting an internal data strobe signal according to an external data strobe signal, a gate circuit receiving the internal data strobe signal output from the input buffer and prohibiting a passage of the internal data strobe signal in response to a first control signal being set to an inactivation level, a latch circuit responsive to each of leading and trailing edges included in the internal data strobe signal passed through the gate circuit for sequentially latching 2N data signals, and a control circuit responsive to Nth trailing edge of the internal data strobe signal for setting the first control signal to the inactivation level. Therefore, since the input of the internal data strobe signal to the latch circuit is prohibited in response to the last trailing edge of the internal data strobe signal, the latch circuit does not malfunction even if a glitch occurs in the external data strobe signal after a postamble period.

Preferably, the input of 2N data signals is started a predetermined time after a write command signal indicative of writing a data is input. The semiconductor memory device further includes a signal generation circuit for setting a second control signal to an activation level in response to the write command signal being input and for setting the second control signal to an inactivation level at predetermined timing between N-1th trailing edge and Nth trailing edge included in the internal data strobe signal. The control circuit sets the first control signal to an activation level in response to the second control signal being set to the activation level, and sets the first control signal to an inactivation level in response to a trailing edge of the internal data strobe signal after the second control signal changes from the activation level to the inactivation level. In this way, the control circuit can be easily configured.

More preferably, the external data strobe signal has one level at a first potential and the other level at a second potential, and the reference potential is between the first potential and the second potential. The input buffer detects whether the external data strobe signal is higher than the reference potential to set the internal data strobe signal to a first level, if higher, and to set the internal data strobe signal to a second level, if lower. Here, the level of the internal data strobe signal changes in synchronization with the level change of the external data strobe signal.

More preferably, further provided is a timing adjustment circuit for delaying the internal data strobe signal to adjust the timing for the latch circuit to latch the data signal. In this way, the data signal can be surely latched.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram showing an overall configuration of a DDR SDRAM in accordance with an embodiment of the present invention.

FIG. 2 is a circuit block diagram showing configurations of a part of a memory array shown in FIG. 1 and a part associated therewith.

FIG. 3 is a block diagram showing a part associated with a data input of an IO buffer shown in FIG. 1.

FIG. 4 is a circuit diagram showing a configuration of an input buffer 20 shown in FIG. 3.

FIG. 5 is a circuit diagram showing a configuration of an input buffer 21 shown in FIG. 3

FIG. 6 is a circuit diagram showing a configuration of a timing adjustment circuit shown in FIG. 3.

FIG. 7 is a circuit diagram showing a configuration of a glitch elimination circuit shown in FIG. 3.

FIG. 8 is a time chart showing an operation of the glitch elimination circuit shown in FIG. 7.

FIG. 9 is a time chart illustrating a timing margin of a falling edge of a signal DSWP shown in FIG. 8.

FIG. 10 is a time chart showing a write operation of DDR SDRAM shown in FIGS. 1-9.

FIG. 11 is a time chart showing a write operation of a conventional DDR SDRAM.

### DESCRIPTION OF THE PREFERRED EMBODIMENTS

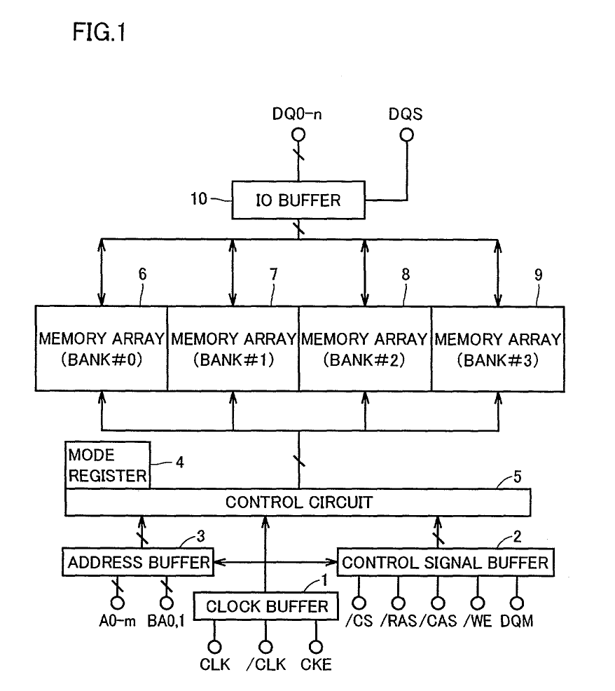

FIG. 1 is a schematic block diagram showing a configuration of a DDR SDRAM in accordance with an embodiment of the present invention. In FIG. 1, this DDR SDRAM includes a clock buffer 1, a control signal buffer 2, an address buffer 3, a mode register 4, a control circuit 5, four memory arrays 6-9 (banks #0-#03), and an IO (input/output) buffer 10.

Clock buffer 1 is activated by an external control signal CKE and transmits external clock signals CLK, /CLK to control signal buffer 2, address buffer 3 and control circuit 5. Control signal buffer 2 latches and applies external control signals /CS, /RAS, /CAS, /WE and DQM to control circuit 5 in synchronization with external clock signals CLK, /CLK from clock buffer 1. Address buffer 3 latches and applies external address signals A0-Am (where m is an integer equal to or larger than 0) and bank select signals BA0, BA1 to control circuit 5 in synchronization with external clock signals CLK, /CLK from clock buffer 1.

Mode register 4 stores a mode indicated by external address signals A0-Am etc. and outputs an internal command signal according to that mode. Each of memory arrays 6-9 includes a plurality of memory cells arranged in rows and columns, each storing one-bit data. The plurality of memory cells are preliminarily divided into a group of n+1 cells (where n is an integer equal to or larger than 0).

Control circuit 5 produces various internal signals according to signals from clock buffer 1, control signal buffer 2, address buffer 3 and mode register 4, to control an entire SDRAM. In reading and writing operations, control circuit 5 selects any of four memory arrays 6-9 according to bank select signals BA0, BA1, and selects n+1 memory cells in that memory array according to address signals A0-Am. The selected n+1 memory cells are activated and coupled to IO buffer 10.

IO buffer 10, in a writing operation, applies data D0-Dn input in synchronization with external data strobe signal DQS to the selected n+1 memory cells, and in a reading operation, outputs data Q0-Qn read from the n+1 memory cells together with data strobe signal DQS to the outside.

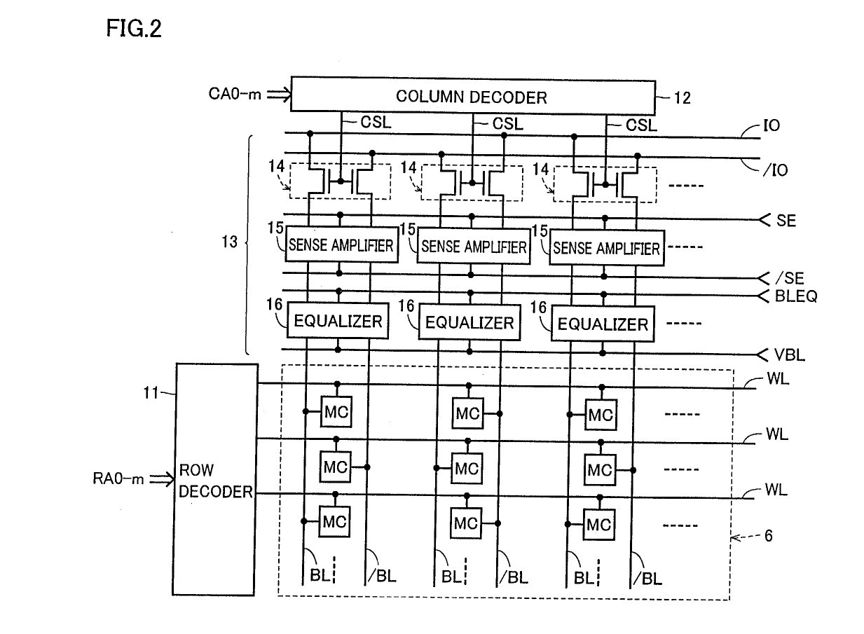

FIG. 2 is a circuit block diagram showing the configuration of that part of memory array 6 in FIG. 1 which corresponds to one data signal DQn, and the part associated therewith. In FIG. 2, memory array 6 includes a plurality of memory cells MC arranged in rows and columns, a word line WL provided corresponding to each row, and a bit line pair BL, /BL provided corresponding to each column. Memory cell MC is a well-known one including N-channel MOS transistor for access and a capacitor for information storage.

Corresponding to memory array 6, there are provided a row decoder 11, a column decoder 12 and a sense amplifier+input/output control circuit 13. Sense amplifier+input/output control circuit 13 includes a data input/output line pair IO, /IO, and a column select gate 14, sense amplifier 15 and an equalizer 16 provided corresponding to each column of memory array 6.

Column select gate 14 includes a pair of N-channel MOS transistors between a bit line pair BL, /BL in a corresponding column and data input/output line pair IO, /IO. The gate of each N-channel MOS transistor is connected with column decoder 12 through a column select line CSL in a corresponding column. When column decoder 12 brings column select line CSL up to “H (high)” level of a select level, N-channel MOS transistor will conduct, and bit line pair BL, /BL and data input/output line pair IO, /IO will be coupled.

Sense amplifier 15 amplifies a small potential difference between the pair of bit lines BL and /BL to a power supply voltage VCC in response to sense amplifier activation signals SE, /SE respectively going to “H” level and “L” level. Equalizer 16 equalizes the potential between bit lines BL and /BL to a bit line precharge potential VBL in response to a bit line equalization signal BLEQ going to “H” level of an activation level.

Row decoder 11 brings one of the plurality of word lines WL to a select level of “H” according to row address signals RA0-RAm (external address signals A0-Am when external control signal /RAS is at “L”).

Column decoder 12 brings any of the plurality of column select lines CSL to a select level of “H” according to column address signals CA0-CAm (external address signals A0-Am when external control signal /CAS is at “L” level). The other memory arrays 7-9 are configured similar to memory array 6.

An operation of SDRAM shown in FIGS. 1 and 2 will now be described. For the sake of simplicity, writing/reading of only one data DQn in one memory array 6 will be described.

In a reading mode, a bit line equalization signal BLEQ is first lowered to “L” level to stop equalization of bit line pair BL, /BL. Then, row decoder 11 brings a word line WL in a row corresponding to row address signals RA0-RAm to a select level of “H”, so that an N-channel MOS transistor of memory cell MC in that row is rendered conductive. This changes the potential between bit line pair BL and /BL by a small amount corresponding to the amount of electric charges in the capacitor of the activated memory cell MC.

Then, sense amplifier activation signals SE, /SE are respectively set to “H” level and “L” level to activate sense amplifier 15. When the potential at bit line BL is higher than the potential at bit line /BL by a small amount, the potential at bit line BL is pulled up to “H” level while the potential at bit line /BL is pulled down to “L” level. Conversely, when the potential at bit line /BL is higher than the potential at bit line BL by a small amount, the potential at bit line /BL is pulled up to “H” level while the potential at bit line BL is pulled down to “L” level.

Thereafter, column decoder 12 brings column select line CSL in a column corresponding to column address signals CA0-CAm up to a select level of “H”, so that column select gate 14 in that column is rendered conductive. Data on the selected bit line pair BL, /BL is applied to IO buffer 10 through column select gate 14 and data input/output line pair IO, /IO. IO buffer 10 outputs a read data signal Qn to the outside in synchronization with a rising edge or a falling edge of data strobe signal DQS.

In a writing mode, in a manner similar to the reading mode, equalization of bit line pair BL, /BL is stopped, word line WL in a row corresponding to row address signals RA0-RAm is raised to of a select level of “H”, and then sense amplifier 15 is activated.

Then, column select gate 14 in a column corresponding to column address signals CA0-CAm is rendered conductive, and a selected bit line pair BL, /BL is connected to IO buffer 10 through data input/output line pair IO, /IO. IO buffer 10 takes in external data signal Dn in synchronization with a rising edge or a falling edge of data strobe signal DQS and provides that data signal Dn to the bit line pair BL, /BL in the selected column through data input/output line pair IO, /IO. Write data signal Dn is provided as a potential difference between bit line pair BL and /BL. The capacitor of the selected memory cell MC is provided with electric charges in the amount corresponding to the potential at bit line BL or /BL.

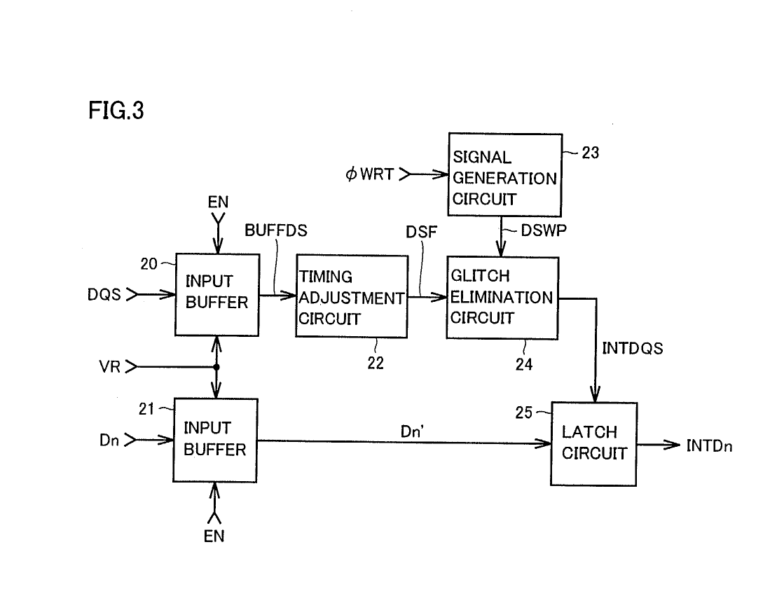

A method of eliminating the effect of glitch G in data strobe signal DQS, which characterizes the present SDRAM, will now be described in detail. FIG. 3 is a block diagram showing a partial configuration in association with a data input of IO buffer 10. In FIG. 3, IO buffer 10 includes input buffers 20, 21, a timing adjustment circuit 22, a signal generation circuit 23, a glitch elimination circuit 24 and a latch circuit 25.

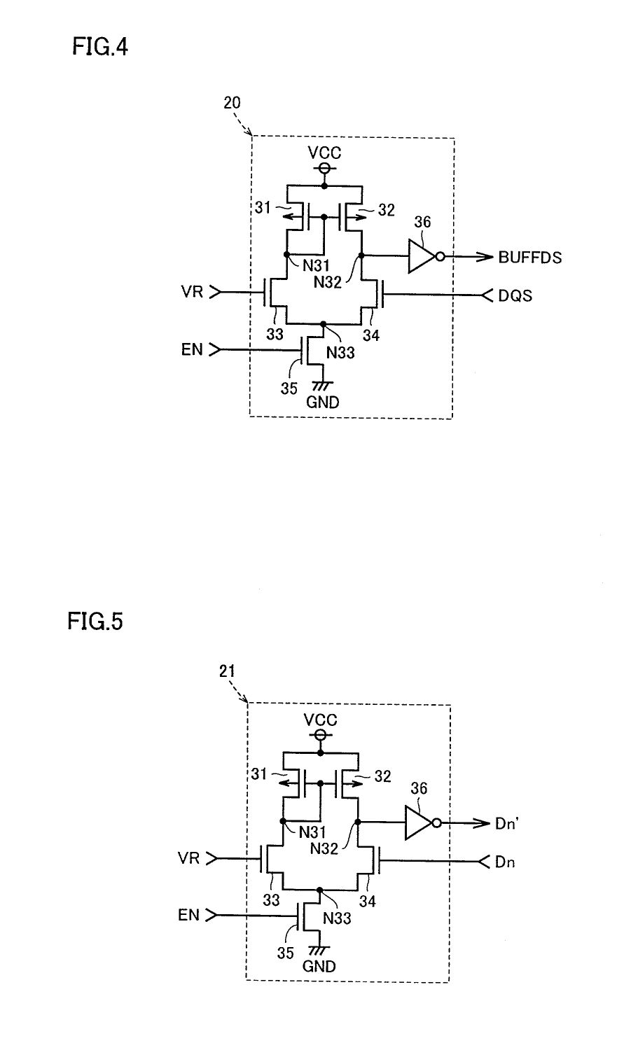

Input buffer 20 includes, as shown in FIG. 4, P-channel MOS transistors 31 and 32, N-channel MOS transistors 33-35 and an inverter 36. P-channel MOS transistors 31 and 32 are respectively connected between a power supply potential VCC line and nodes N31 and N32 and have their gates connected together to node N31. P-channel MOS transistors 31 and 32 configure a current mirror circuit. N-channel MOS transistor 33 is connected between nodes N31 and N33 and has its gate receiving a reference potential VR. Reference potential VR has a prescribed level between “H” level and “L” level. N-channel MOS transistor 34 is connected between nodes N32 and N33 and has its gate receiving signal DQS. N-channel MOS transistor 35 is connected between node N33 and a ground potential GND line, and has its gate receiving a signal EN. A signal appearing at node N32 is inverted by inverter 36 to be an output signal BUFFDS from input buffer 20.

When signal EN is at an inactivation level of “L”, N-channel MOS transistor 35 is rendered nonconductive so that input buffer 20 is inactivated and signal BUFFDS is fixed at “L” level. When signal EN is at an activation level of “H”, N-channel MOS transistor 35 is rendered conductive so that input buffer 20 is activated.

When signal DQS is lower than reference potential VR, current flowing through MOS transistors 31-33 becomes larger than current flowing through N-channel MOS transistor 34, causing node N32 to go to “H” level and signal BUFFDS to go to “L” level. When signal DQS is higher than reference potential VR, current flowing through MOS transistors 31-33 becomes smaller than current flowing through N-channel MOS transistor 34, causing node N32 to go to “L” level and signal BUFFDS to go to “H” level. Output signal BUFFDS from input buffer 20 is applied to timing adjustment circuit 22.

Input buffer 21 has a configuration similar to input buffer 20, as shown in FIG. 5. Input buffer 21 is activated when signal EN is at “H” level of an activation level, and drives a signal Dn′ to “L” level when externally applied write data signal Dn is lower than reference potential VR and drives signal Dn′ to “H” level when write data signal is higher than reference potential VR. Output signal Dn′ from input buffer 21 is applied to latch circuit 25.

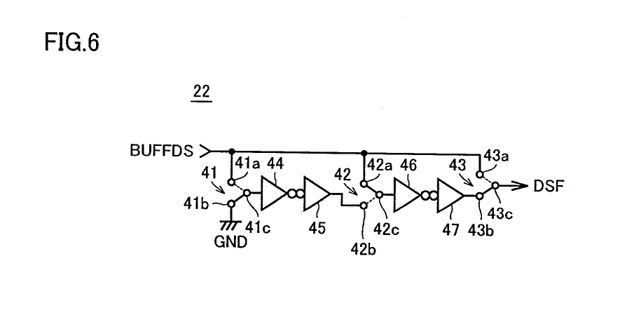

Timing adjustment circuit 22 includes switches 41-43 and inverters 44-47 as shown in FIG. 6. Output signal BUFFDS from input buffer 20 is applied to respective one switching terminals 41a-43a of switches 41-43. The other switching terminal 41b of switch 41 is connected to a ground potential GND line. Inverters 44 and 45 are connected in series between a common terminal 41c for switch 41 and the other switching terminal 42b of switch 42. Inverters 46 and 47 are connected in series between a common terminal 42c for switch 42 and the other switching terminal 43b of switch 43. A signal appearing at a common terminal 43c for switch 43 will be an output signal DSF from this timing adjustment circuit 22.

Switching of switch 41 is effectuated by connecting terminals 41a to 41c or terminals 41b to 41c by means of an aluminum interconnection. The same applies to the other switches 42 and 43. FIG. 6 shows that terminals 41b and 41c of switch 41, terminals 42a and 42c of switch 42, and terminals 43b and 43c of switch 43 are respectively connected by the aluminum interconnection. In this example, signal BUFFDS is delayed at inverters 46 and 47 to be signal DSF.

For example, when terminals 41a and 41c of switch 41, terminals 42b and 42c of switch 42, and terminals 43b and 43c of switch 43 are respectively connected, signal BUFFDS is delayed at inverters 44-47 to be signal DSF. In this example, the delayed time in timing adjustment circuit 22 will be maximized.

Alternatively, when terminals 41b and 41c of switch 41, terminals 42b and 42c of switch 42, and terminals 43a and 43c of switch 43 are respectively connected, signal BUFFDS is not delayed to be signal DSF. Changing the state of connection of switches 41-43 can adjust the timing of signals Dn′ and INTDQS in latch circuit 25.

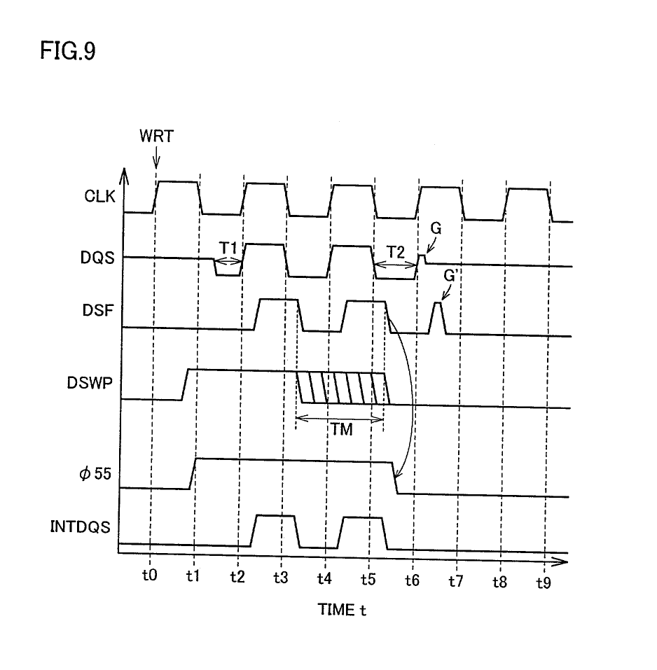

Returning to FIG. 3, signal generation circuit 23 produces a signal DSWP in response to a signal φ WRT. Signal φ WRT is a pulse signal which is produced in response to write command WRT being input. Signal DSWP is raised from “L” level to “H” level in response to signal φ WRT, and is lowered from “H” level to “L” level after a prescribed time period. Timing of level change of signal DSWP will be described later with reference to FIG. 9.

Glitch elimination circuit 24 is controlled by signal DSWP and eliminates glitch G from output signal DSF of timing adjustment circuit 22 to produce a signal INTDQS. Signal DSWP goes to “H” level during a burst write period after write command WRT is input.

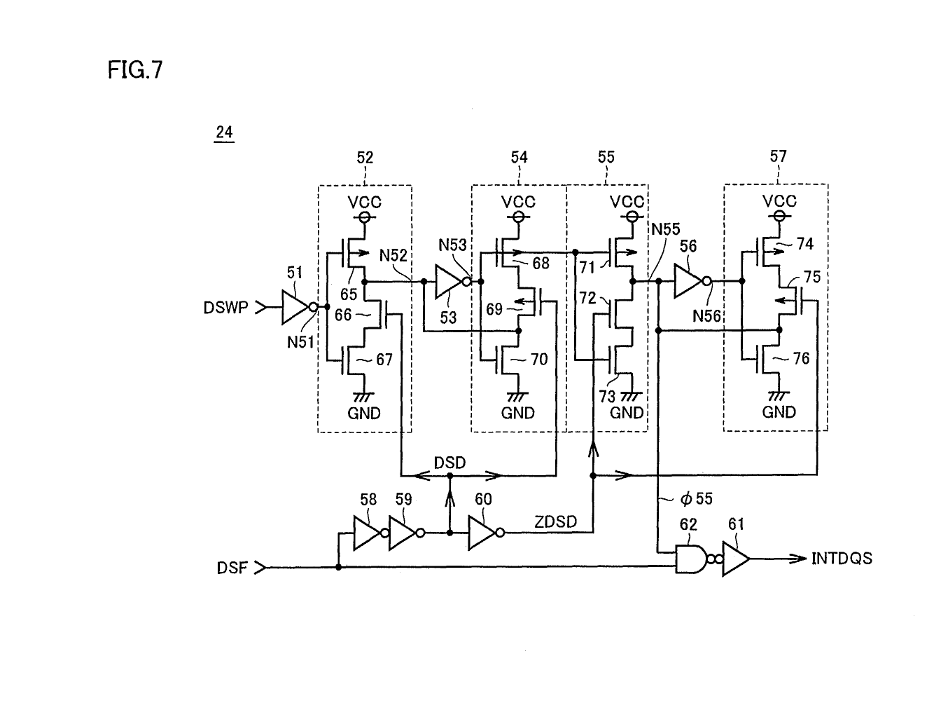

Specifically, glitch elimination circuit 24 includes inverters 51-61 and an NAND gate 62 as shown in FIG. 7. Signal DSWP is input to inverters 54 and 55 through inverters 51-53. Inverter 52 includes a P-channel MOS transistor 65 and N-channel MOS transistors 66 and 67 connected in series between a power supply potential VCC line and a ground potential GND line. MOS transistors 65 and 67 have their gates connected together to an output node N51 of inverter 51. N-channel MOS transistor 66 has its gate receiving a signal DSD. When signal DSD is set to “H” level, N-channel MOS transistor 66 is rendered conductive and inverter 52 is activated.

Inverter 54 includes P-channel MOS transistors 68 and 69 and an N-channel MOS transistor 70 connected in series between the power supply potential VCC line and the ground potential GND line. MOS transistors 68 and 70 have their gates connected together to an output node N53 of inverter 53. P-channel MOS transistor 69 has its gate receiving signal DSD. When signal DSD is set to “L” level, P-channel MOS transistor 69 is rendered conductive and inverter 54 is activated. The output node (the drain of P-channel MOS transistor 69) of inverter 54 is connected to a node N52. Inverters 53 and 54 configure a latch circuit.

Inverter 55 includes a P-channel MOS transistor 71 and N-channel MOS transistors 72 and 73 connected in series between the power supply potential VCC line and the ground potential GND line. MOS transistors 71 and 73 have their gates connected together to output node N53 of inverter 53. N-channel MOS transistor 72 has its gate receiving a signal ZDSD. When signal ZDSD is set to “H” level, N-channel MOS transistor 72 is rendered conductive and inverter 55 is activated. Output node N55 (the drain of P-channel MOS transistor 71) of inverter 55 is connected to an input node of inverter 56.

Inverter 57 includes P-channel MOS transistors 74 and 75 and an N-channel MOS transistor 76 connected in series between the power supply potential VCC line and the ground potential GND line. MOS transistors 74 and 76 have their gates connected together to an output node N56 of inverter 56. P-channel MOS transistor 75 has its gate receiving signal ZDSD. When signal ZDSD is set to “L” level, P-channel MOS transistor 75 is rendered conductive and inverter 57 is activated. The output node (the drain of P-channel MOS transistor 75) of inverter 57 is connected to node N55. Inverters 56 and 57 configure a latch circuit.

Signal DSF is delayed by inverters 58 and 59 to be a signal DSD, which is further inverted by inverter 60 to be signal ZDSD. NAND gate 62 receives signal DSF and a signal φ 55 appearing at node N55. An output signal from NAND gate 62 is inverted by inverter 61 to be signal INTDQS.

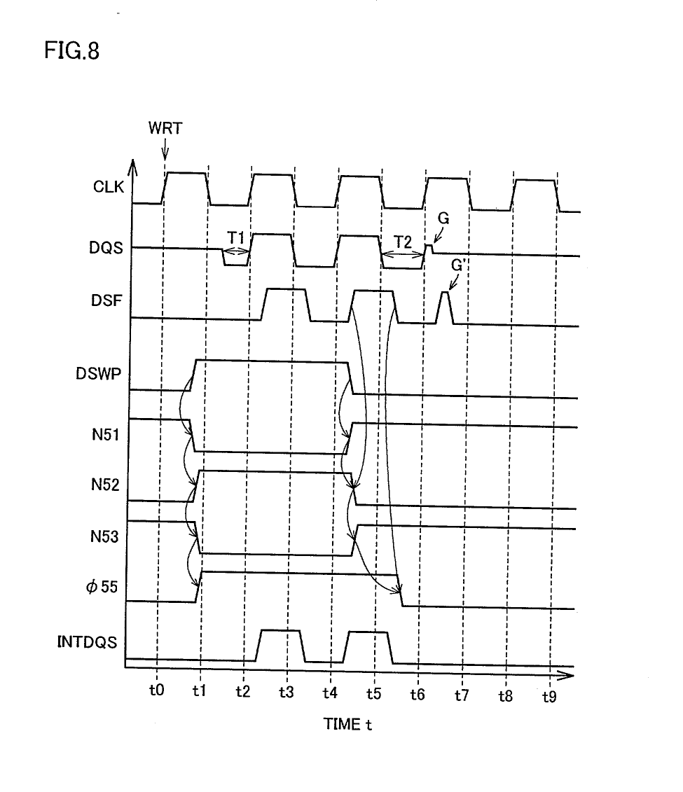

FIG. 8 is a time chart illustrating an operation of glitch elimination circuit 24 shown in FIG. 7. Write command WRT is input in synchronization with one of rising edges (at time t0) of external clock signal CLK, and data strobe signal DQS is input after one clock cycle has elapsed from that rising edge (at time t0). Here, it is assumed that a burst length, that is, the number of successively written data signals is four. Accordingly, four edges of data strobe signal DQS are input. A preamble period T1 is provided before the first rising edge of signal DQS, and a postamble period T2 is provided after the last falling edge of signal DQS, with glitch G arising after the elapse of postamble period T2. Signal DSF is a signal produced by converting signal DQS into a binary signal, which is then delayed. Therefore, signal DSF has two pulse signals and a glitch G′.

On the other hand, signal DSVVP is a signal which is driven to “H” level during a burst write operation period after write command WRT is input. The rising of signal DSWP from “L” level to “H” level brings output node N51 of inverter 51 down to “L” level, output node N52 of inverter 52 up to “H” level, output node N53 of inverter 53 down to “L” level, and signal φ 55 up to “H” level. This state is not affected by the level changes of signals DSF, DSD and ZDSD. While signal φ 55 is being at “H” level, signal DSF passes through NAND gate 62 and inverter 61 to be signal INTDQS.

Next, signal DSWP is lowered from “H” level to “L” level during the period between two falling edges of signal DSF, causing output node N51 of inverter 51 to rise from “L” level to “H” level.

(1) At this time, if signal DSF is at “L” level, MOS transistors 65 and 66 of inverter 52 will be nonconductive, and the levels at nodes N52 and N53 are latched by inverters 53 and 54. Therefore, nodes N52 and N53 and signal φ 55 remain unchanged at “H” level, “L” level and “H” level, respectively.

(2) On the other hand, if signal DSF is at “H” level, node N52 is lowered from “H” level to “L” level, node N53 is raised from “L” level to “H” level, and the levels at nodes N52 and N53 are latched by inverters 53 and 54. Further, MOS transistors 71 and 72 of inverter 55 will be nonconductive, and the levels at nodes N55 and N56 are latched by inverters 56 and 57. Therefore, signal φ 55 and node N56 are held at “H” level and “L” level, respectively.

(3) Following (2), when signal DSF is lowered from “H” level to “L” level, the levels at nodes N52 and N53 remain unchanged at “L” level and “H” level, respectively, since they are latched by inverters 53 and 54. As node N53 is at “H” level and signal ZDSD goes to “H” level, however, output signal φ 55 of inverter 55 is lowered to “L” level. The levels at nodes N55 and N56 are latched by inverters 56 and 57, and signal φ 55 and node N56 are held at “H” level and “L” level, respectively.

(4) Following (3), when signal DSF is raised from “L” level to “H” level, the levels at nodes N52 and N53 remain unchanged at “L” level and “H” level, respectively, since they are latched by inverters 53 and 54. Since the levels at nodes N55 and N56 are also latched by inverters 56 and 57, signal φ 55 and node N56 remain unchanged at “L” level and “H” level, respectively.

As described above, when signal DSWP falls from “H” level to “L” level, signal φ 55 changes to “L” level through the path of (2)→(3) or (1)→(2)→(3), and thereafter is fixed at “L” level even if signal DSF is raised from “L” level to “H” level in (4). With signal φ 55 at “L” level, an output signal from NAND gate 62 is fixed at “H” level and signal INTDQS is fixed at “L” level.

In summary, signal φ 55 is set to “H” level when signal DSWP is raised from “L” level to “H” level, and is reset to “L” level when signal DSF is lowered from “H” level to “L” level after signal DSWP is lowered from “H” level to “L” level. Therefore, even if there are glitches G and G′ in signals DQS and DSF, a glitch does not appear in signal INTDQS.

The timing of level change of signals DSWP and DSF (DQS) will now be described. The rising of signal DSWP from “L” level to “H” level may be completed from the input of write command WRT to preamble period T1 of signal DQS.

The falling of signal DSWP from “H” level to “L” level may be within the period TM between the last falling edge (excluding glitch G′) and the previous falling edge of signal DSF, as shown in FIG. 9, since signal DSF is lowered from “H” level to “L” level after the falling of signal DSWP from “H” level to “L” level, and then signals φ 55 and INTDQS are fixed at “L” level.

A timing shift occurs between external clock signal CLK and signal DQS by at most ±0.25 clock cycle. Since there is a timing margin by one clock cycle between the falling edge of signal DSWP synchronized with external clock signal CLK and the falling edge of signal DSF synchronized with signal DQS, timing margin can be considered sufficient even if the timing shift of ±0.25 clock cycle at maximum occurs between signal DSWP and signal DSF.

Returning to FIG. 3, output signal INTDQS from glitch elimination circuit 24 is applied to latch circuit 25. Latch circuit 25 holds and outputs output signal Dn′ from input buffer 21 in response to each of rising and falling edges of signal INTDQS. Output signal INTDn from latch circuit 25 is written into a selected memory cell MC.

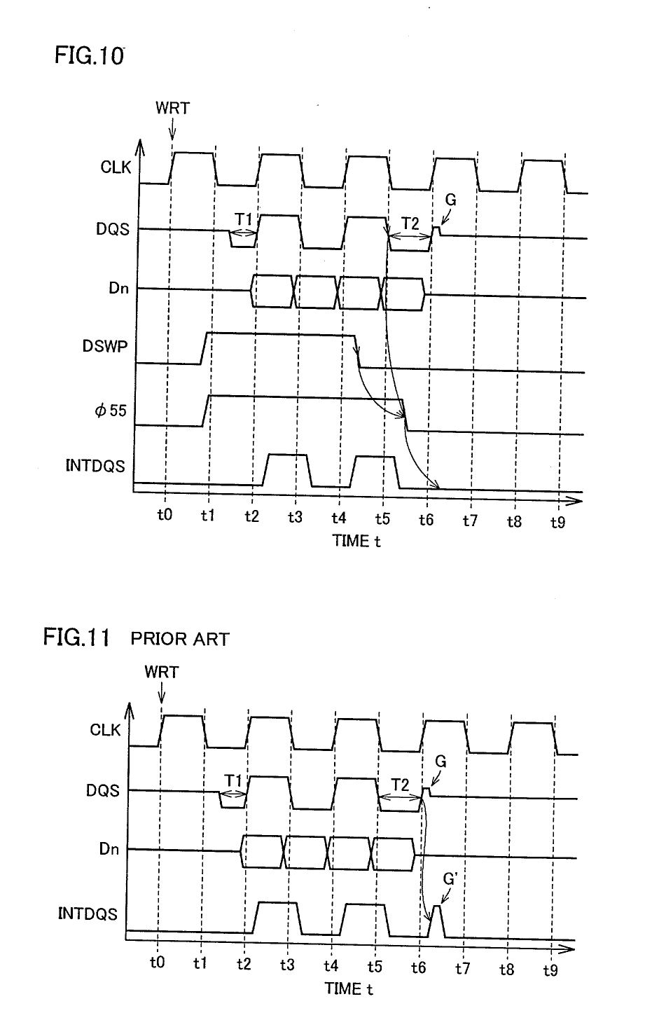

FIG. 10 is a time chart illustrating an operation in a writing mode of DDR SDRAM shown in FIGS. 1-9. One clock cycle after write command WRT being input, data strobe signal DQS and write data signal Dn are input in synchronization with clock signal CLK. Four data signals Dn are input in synchronization with rising and falling edges of signal DQS. It is assumed that glitch G occurs after the elapse of postamble period T2 of signal DQS.

On the other hand, in response to the input of write command WRT, signals DSWP and φ 55 are raised to “H” level. During the period in which signal φ 55 is at “H” level, signal INTDQS is produced based on signal DQS. Signal INTDQS is a signal produced by converting signal DQS into a binary signal, which is delayed for a prescribed amount of time.

When signal DQS is lowered from “H” level to “L” level after the falling of signal DSWP from “H” level to “L” level, signal φ 55 is driven from “H” level to “L” level, and then signal INTDQS is fixed at “L” level. Therefore, even if glitch G arises in signal DQS, latch circuit 24 is prevented from malfunctioning by the occurrence of glitch G′ in signal INTDQS.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor memory device, receiving 2N data signals successively input in synchronization with N pairs of leading edge and trailing edge included in an external clock signal (N is a natural number) and an external data strobe signal having N pairs of leading edge and trailing edge synchronized with said 2N data signals and driven to a reference potential after elapse of a postamble period following the last trailing edge, and taking in said 2N data signals in synchronization with N pairs of leading edge and trailing edge included in said external data strobe signal, comprising:
an input buffer outputting an internal data strobe signal according to said external data strobe signal;
a gate circuit receiving the internal data strobe signal output from said input buffer and prohibiting a passage of said internal data strobe signal in response to a first control signal being set to an inactivation level;
a latch circuit responsive to each of leading and trailing edges included in the internal data strobe signal passed through said gate circuit for sequentially latching said 2N data signals; and
a control circuit responsive to Nth trailing edge of said internal data strobe signal for setting said first control signal to the inactivation level.

2. The semiconductor memory device according to claim 1, wherein
an input of said 2N data signals is started a predetermined time after a write command signal indicative of writing a data is input, the semiconductor memory device further comprising
a signal generation circuit setting a second control signal to an activation level in response to said write command signal being input, and setting said second control signal to an inactivation level at predetermined timing between N-1th trailing edge and Nth trailing edge included in said internal data strobe signal, wherein
said control circuit sets said first control signal to an activation level in response to said second control signal being set to the activation level, and sets said first control signal to an inactivation level in response to a trailing edge of said internal data strobe signal after said second control signal changes from the activation level to the inactivation level.

3. The semiconductor memory device according to claim 1, wherein
said external data strobe signal has one level at a first potential and the other level at a second potential, said reference potential being between said first potential and said second potential, and
said input buffer detects whether said external data strobe signal is higher than said reference potential, to set the internal data strobe signal to a first level, if higher, and to set said internal data strobe signal to a second level, if lower.

4. The semiconductor memory device according to claim 1, further comprising a timing adjustment circuit for delaying said internal data strobe signal to adjust timing for said latch circuit to latch said data signal.
